(19) United States
(12) Patent Application Publication
(10) Pub. No.: US 2008/0142945 A1
(43) Pub. Date: Jun. 19, 2008

(54) SEMICONDUCTOR PACKAGE WITH REDISTRIBUTION LAYER OF SEMICONDUCTOR CHIP DIRECTLY CONTACTED WITH SUBSTRATE AND METHOD OF FABRICATING THE SAME

(75) Inventors: Seung-Weon HA, Chungcheongnam-do (KR); Sang-Gug LEE, Gyeonggi-do (KR); Ho-Tae Jin, Chungcheongnam-do (KR); Doo-Ho KANG, Chungcheongbuk-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/960,473

(22) Filed: Dec. 19, 2007

(30) Foreign Application Priority Data
Dec. 19, 2006 (KR) 2006-0130450

(51) Int. Cl. H01L 23/02

(52) U.S. Cl. 257/686; 257/E23.085

(57) ABSTRACT

Provided are a semiconductor package in which wiring layers connected to a semiconductor chip electrically contact circuit patterns of a substrate and a method of manufacturing the same. The semiconductor package includes the substrate and the semiconductor chip. The substrate includes a first concave portion disposed on the upper surface thereof and a plurality of the circuit patterns disposed adjacent to the first concave portion. The semiconductor chip is mounted in the substrate to correspond to the concave portion. The semiconductor chip comprises a wafer, pads disposed on the wafer, and wiring layers disposed on the upper surface and on one side surface of the wafer, wherein first portions disposed on the upper surface of the wafer are connected to the pads and second portions disposed on the one side surface of the wafer contact the circuit patterns of the substrate.

### CROSS-REFERENCE TO RELATED PATENT APPLICATION

This application claims priority under 35 USC §119 to Korean Patent Application No. 10-2006-130450, filed on Dec. 19, 2006 in the Korean Intellectual Property Office, the contents of which are incorporated herein in their entirety by reference.

### BACKGROUND

1. Technical Field

The present invention relates to a semiconductor package, and more particularly, to a semiconductor package in which a wiring layer of a semiconductor chip is electrically connected directly to a substrate and a method of manufacturing the same.

2. Description of the Related Art

A semiconductor package is used for electrically connecting input and output terminals of semiconductor chips to external circuits as well as for protecting the semiconductor chips. As electronic devices become smaller, lighter and have higher performance, semiconductor packages which are smaller and lighter as well as more economic and reliable are required. Accordingly, packages such as a flip chip package, a wafer level package, a wafer level stack package and the like, which do not require a wire bonding method, have been developed.

In wafer level packages, assembly or packaging of semiconductor chips is completed at a wafer level and processing on all semiconductor chips on a wafer are performed together until an assembly process is completed. Thus, not only the manufacturing costs of semiconductor devices can be reduced but also the performance of packages and semiconductor chips can be more consistent. Also, thermal and electrical characteristics of semiconductor devices are improved and the size of the packages can be minimized to near the size of the semiconductor chips.

Conventionally, complex processes such as a laser drilling process, a passivation deposition process, a passivation layer etching process, etc., are required to manufacture a wafer level stack package, and accordingly the manufacturing costs and time are increased.

The present invention addresses these and other disadvantages of the conventional art.

### SUMMARY

The present invention provides a semiconductor package for which a process is simplified by directly electrically contacting a semiconductor chip to a substrate, and a method of manufacturing the same.

According to an aspect of the present invention, there is provided a semiconductor package in which a semiconductor chip is electrically connected to a substrate. The semiconductor package comprises a substrate and a semiconductor chip. The substrate comprises a first concave portion formed on the upper surface thereof and a plurality of circuit patterns disposed adjacent to the first concave portion. The semiconductor chip is mounted on the substrate so as to correspond to the first concave portion. The semiconductor chip comprises: a wafer; pads disposed on the wafer; and wiring layers disposed on the upper surface and one side surface of the wafer, in which first portions of the wiring layers disposed on the upper surface of the wafer are connected to the pads and second portions of the wiring layers disposed on the side surface of the wafer contact the circuit patterns.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a semiconductor package in which a semiconductor chip directly contacts a substrate according to an embodiment of the present invention;

FIGS. 2A through 2N are cross-sectional views illustrating a method of manufacturing the semiconductor chip of the semiconductor package of FIG. 1 according to an embodiment of the present invention;

FIGS. 3A through 3B are perspective views illustrating a process of attaching the semiconductor chip fabricated by the method of FIGS. 2A through 2N on a substrate, according to an embodiment of the present invention; and

FIG. 4 is a cross-sectional view of a semiconductor package according to another embodiment of the present invention.

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

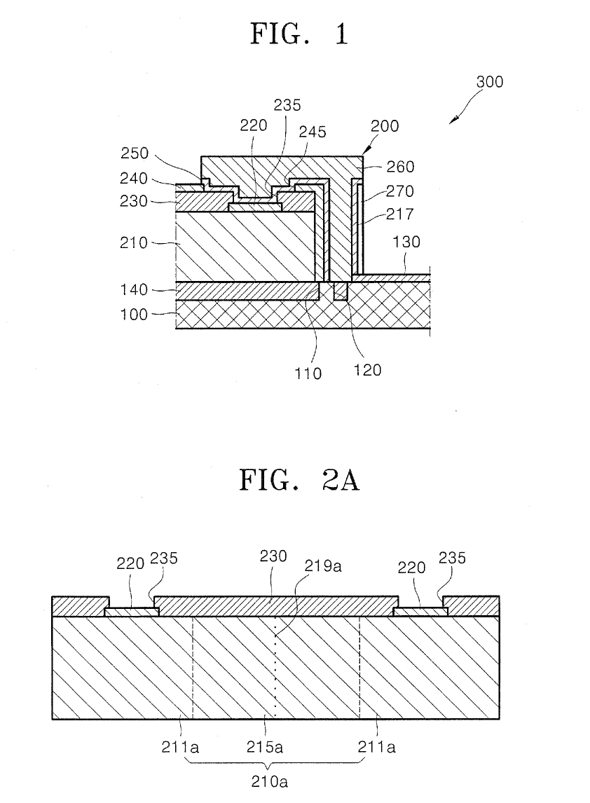

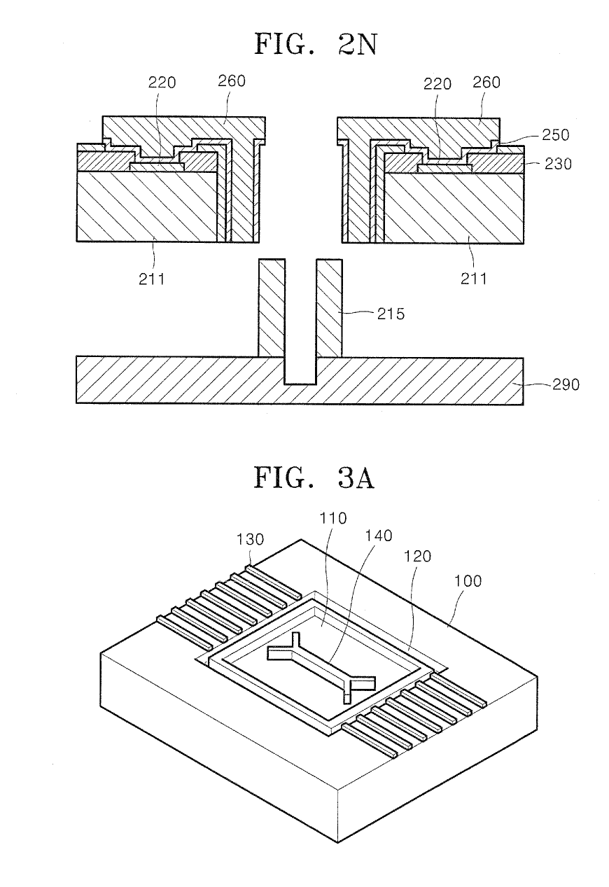

FIG. 1 is a cross-sectional view illustrating a semiconductor package 300 according to an embodiment of the present invention. Referring to FIG. 1, the semiconductor package 300 includes a substrate 100 and a semiconductor chip 200. The substrate 100 may include a printed circuit board (PCB). The substrate 100 includes a first concave portion 110 which is formed corresponding to a portion where the semiconductor chip 200 is mounted, and a second concave portion 120 which is formed in a closed curve shape so as to surround the first concave portion 110 (as shown in FIG. 3A). The substrate 100 includes a plurality of circuit patterns 130 which are arranged between the second concave portion 120 and an edge portion of the substrate 100 and contact the second concave portion 120.

The semiconductor chip 200 includes a wafer 210, pads 220 disposed on the wafer 210 and a wiring layer 260 for electrically connecting the pads 220, and the circuit patterns 130 of substrate 100. The pads 220 can include a metal pad such as an Al pad. The pads 220 are exposed through an opening portion 235 of a first insulation layer 230, and the first insulation layer 230 can include a protection layer. The wiring layer 260 electrically connects the pads 220 and the circuit patterns 130. The wiring layer 260 is arranged above the first insulation layer 230 and on one side of the wafer 210. The wiring layer 260 can include an Al plating layer. A first portion of the wiring layer 260 arranged above the first insulation layer 230 is connected to the pads 220 exposed through the opening portion 235, and a second portion of the wiring layer 260, formed in a via-hole 217 and arranged on the one side of wafer 210, is connected to the circuit patterns 130 of substrate 100. The circuit patterns 130 are illustrated as protruding from the upper surface of the substrate 100 according to the current embodiment of the present invention. However, the substrate 100 can include a third concave portion corresponding to the circuit patterns 130 besides the first and second concave portions 110 and 120 and the circuit patterns 130 can be disposed in the third concave portion.

The semiconductor chip 200 is arranged so as to correspond to the first concave portion 110 of the substrate 100 and is bonded to the substrate 100 by an adhesive 140. The second portion of the wiring layer 260 is arranged so as to correspond to the second concave portion 120, and the circuit patterns 130 directly contact one side of the second portion of wiring layer 260 without wires or a wire bonding process. The second concave portion 120 can be arranged in a closed curve shape to surround the first concave portion 110. Moreover, the second concave portion 120 can be arranged into a plurality of portions respectively corresponding to the circuit patterns 130.

A second insulation layer 240 is formed on the first insulation layer 230 and one side of the wafer 210 and includes an opening portion 245 to expose the pad 220 and a portion of the first insulation layer 230. Also, the second insulation layer 240 includes the via-holes 217 corresponding to the second concave portion 120, and the second portion of the wiring layer 260 is disposed in the via-holes 217. An adhesive layer 270 is formed on sides of the wiring layer 260 disposed in the via-holes 217 to improve the adhesion between the wiring layer 260 and the circuit patterns 130 of the substrate 100. The adhesive layer 270 can include an Al plating layer. A seed layer 250 is formed on the first and second insulation layers 230 and 240 and in the via-holes 217. The seed layer 250 is disposed below the wiring layer 260 and is connected to the pads 220 and the circuit patterns 130.

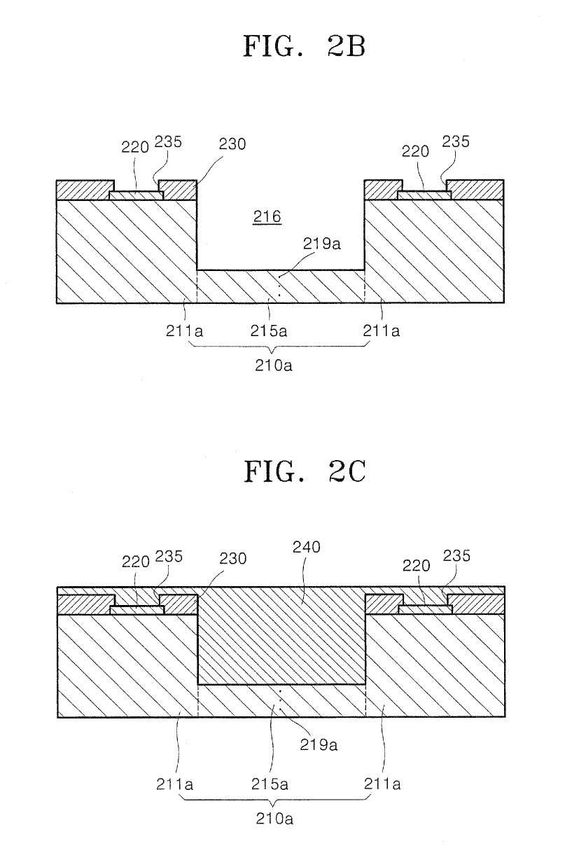

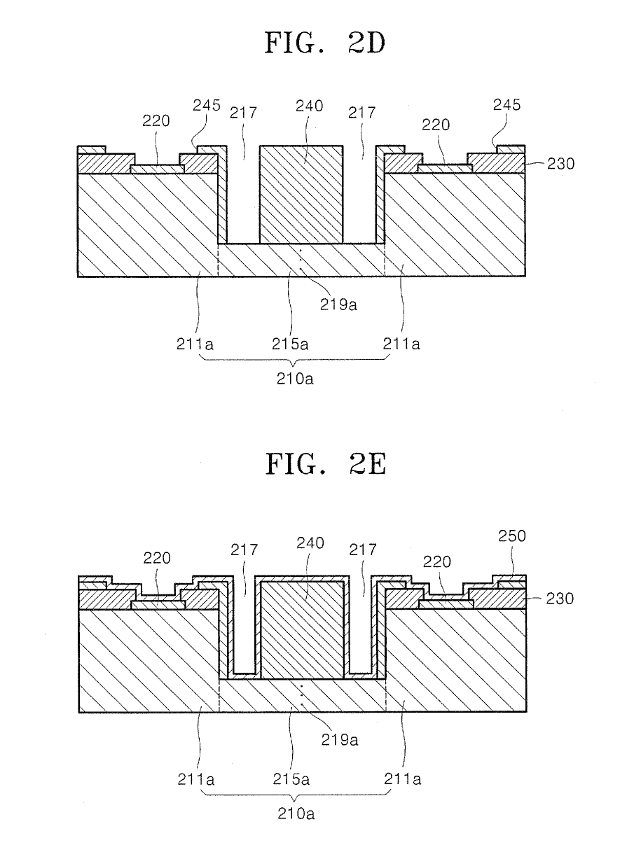

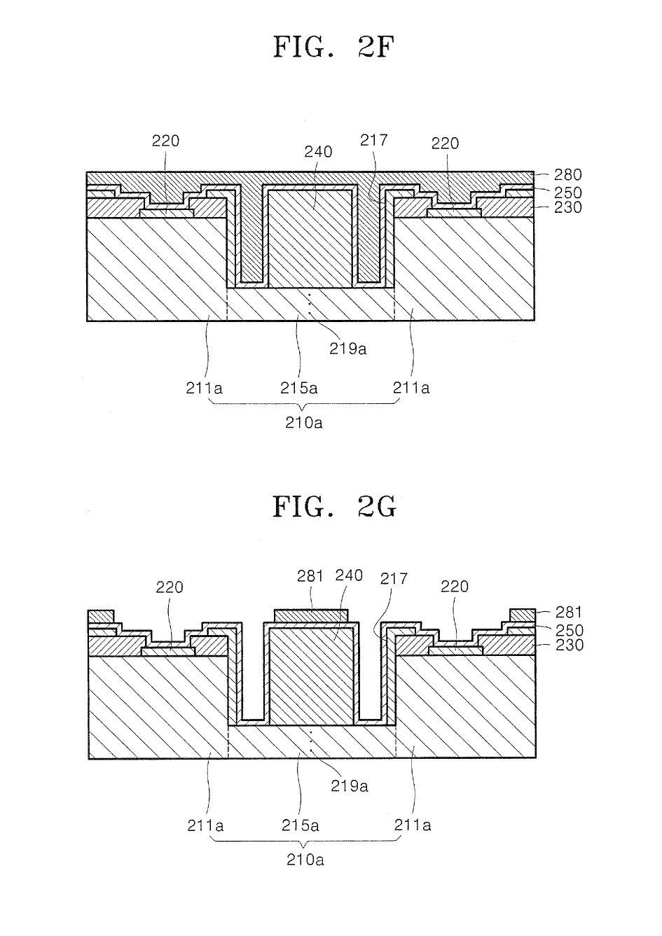

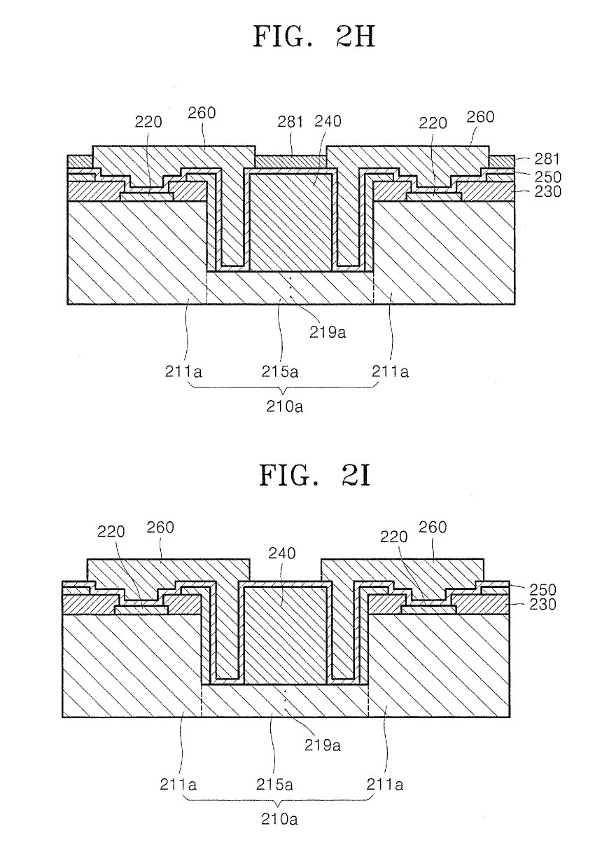

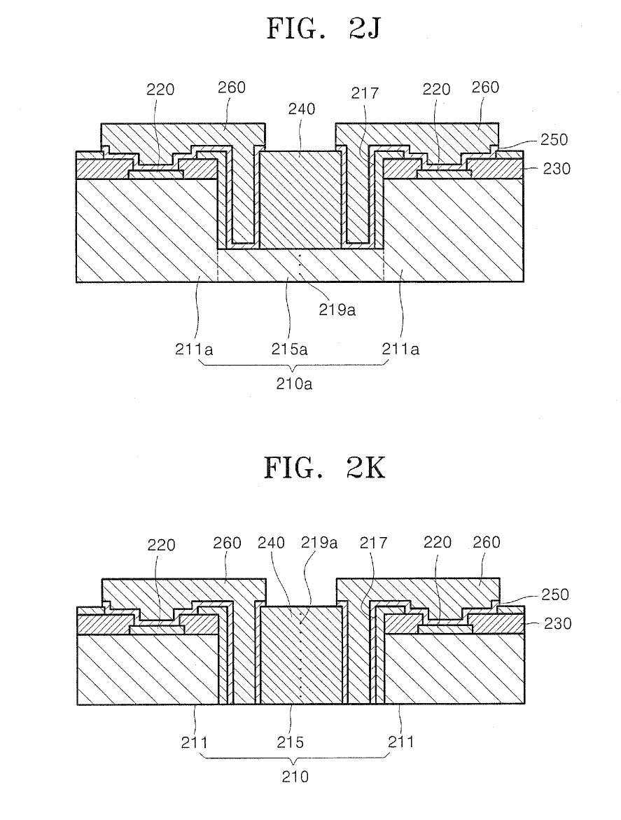

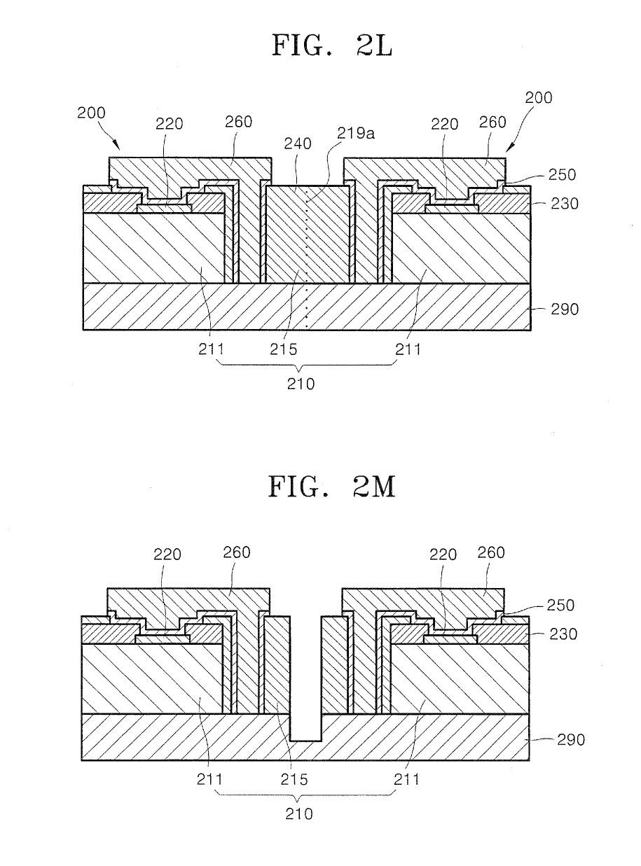

FIGS. 2A through 2N are sectional views for illustrating a method of manufacturing a semiconductor package according to an embodiment of the present invention. Referring to FIG. 2A, a semiconductor wafer 210a is provided. The semiconductor wafer 210a includes a plurality of semiconductor chip areas 211a defined by a scribe area 215a in which a scribe line 219a is arranged. Semiconductor devices (not shown) can be arranged in the semiconductor chip area 211a during semiconductor manufacturing processes. A plurality of pads 220 are respectively disposed on the semiconductor chip areas 211a. The pads 220 can electrically connect the semiconductor devices arranged in the semiconductor chip areas 211a to external circuits. The pads 220 may be metal pads including Al pads. The pads 220 are disposed on the semiconductor chip areas 211a adjacent to the scribe area 215a and can be disposed in rows corresponding to the circuit patterns 130 of the substrate 100 of FIG. 3A. A first insulation layer 230 defining openings 235, which expose portions of the pads 220, is formed on the wafer 210a. The first insulation layer 230 is a protection layer and can include a nitride film and/or an oxide film.

Referring to FIG. 2B, a concave portion 216 is formed by etching the first insulation layer 230 and the wafer 210a in the scribe area 215a. The thickness of the wafer 210a remaining in the scribe area 215a or the depth of the concave portion 216 can be determined according to the thickness of wafer to be removed during a subsequent lapping process of the bottom surface of the wafer 210a. The concave portion 216 can be formed by a sawing method using a blade, which is generally used for wafer cutting, or a conventional photo/etching method.

Referring to FIGS. 2C and 2D, a second insulation layer 240 is formed on the wafer 210a so as to substantially fill the concave portion 216. The second insulation layer 240 is etched to form the openings 245 in the semiconductor chip areas 211a. The openings 245 are formed so as to expose portions of the pads 220 and portions of the first insulation layer 230 adjacent to the pads 220. The via-holes 217 in which wiring layers are formed in a subsequent process are disposed in the scribe area 215a adjacent to the semiconductor chip area 211a on both sides of the scribe line 219a. The via-holes 217 are formed by etching the second insulation layer 240 until the wafer 210a in the scribe area 215a is exposed.

According to some embodiments of the present invention, the via-holes are formed by a photo/etching process after filling the concave portion 216 in the scribe area 215a with the second insulation layer 240 formed of an interlayer insulating layer. Thus, a drilling process for forming the via-holes 217 as well as a deposition and patterning processes of forming a passivation layer, etc., as used in a conventional manufacturing process for semiconductor packages, can be omitted.

Referring to FIG. 2E, the seed layer 250 is formed on the entire surface of the wafer 210a. The seed layer 250 is formed to contact the pads 220 in the semiconductor chip areas 211a and formed inside the via-holes 217. The seed layer 250 is formed by depositing metal layers using a sputtering method, for example. The seed layer 250 can be formed of a metal having excellent adhesion to the second insulation layer 240 and excellent wetting to the wiring layer which is to be formed in a subsequent process. Examples of the metal having excellent adhesion to the second insulation layer include Cr or Ti, and examples of the metal having excellent wetting to the wiring layer include Ag, Au, Cu, Ni, Pd, Pt, etc. Therefore, the seed layer 250 may include Ti/Cu, Ti/Pd, Ti/Pt, Ti/Ni, Cr/Cu, etc.

Referring to FIGS. 2F and 2G, a photoresist film 280 is coated on the seed layer 250 and is patterned so as to be removed in a portion where the subsequent wiring layer is to be formed. As a result, photoresist film patterns 281 are formed and thus portions of the seed layer 250 corresponding to the pads 220 and the via-holes 217 are exposed.

Referring to FIGS. 2H and 2I, the wiring layers 260 are formed on the exposed portions of the seed layer 250 using an electroplating process. The wiring layers 260 can include metals having excellent wetting to the seed layer such as Ag, Au, Cu, Ni, Pd, or Pt or an alloy layer thereof. Next, the photoresist film patterns 281 are removed.

Referring to FIGS. 2J and 2K, portions of the seed layer 250, which are exposed by removing the photoresist film patterns 281, are etched so that the second insulation layer 240 can be exposed. Subsequently, the rear surface of the wafer 210a is lapped. The lapping process can be performed until the seed layer 250 formed in the bottom surface of via-holes 217 is etched to expose the wiring layer 260.

Referring to FIGS. 2L, 2M and 2N, an adhesive tape 290 is attached to the lapped rear surface of the wafer 210. The adhesive tape 290 can be an ultraviolet tape. Subsequently, the second insulation layer 240 and the adhesive tape 290 in the scribe region 215 are cut along the scribe line 219a. At this time, only a portion of the adhesive tape 290 is cut so that the remaining portion can support the semiconductor chip 200 disposed in the cut semiconductor wafer 210. The adhesive tape 290 and a portion of the second insulation layer 240 in the scribe region 215 are removed from the semiconductor chip 200 by irradiating ultraviolet rays on the adhesive tape 290, thereby forming a separated individual semiconductor chip 200.

FIGS. 3A and 3B are perspective views for illustrating a method of mounting the semiconductor chip 200 on the substrate. Referring to FIGS. 3A and 3B, a substrate 100 on which the semiconductor chip 200 is to be mounted is arranged. The substrate 100 includes a first concave portion 110 disposed where the semiconductor chip 200 is to be mounted and a plurality of circuit patterns 130 disposed adjacent to the first concave portion 110. The circuit patterns 130 can be arranged in rows on two sides of the first concave portion 110. Alternatively, the circuit patterns 130 may be arranged in rows on a single side or three or more sides of the first concave portion 110. The size of the first concave portion 110 substantially corresponds to the size of the semiconductor chip 200. An adhesive 140 is coated on the bottom surface of the first concave portion 110. The substrate 100 further includes a second concave portion 120 to prevent the adhesive agent 140 coated on the first concave portion 110 from overflowing to the circuit patterns 130. The second concave portion 120 is formed in a closed curve shape to surround the first concave portion 110. The second concave portion 120 may included one or more concave portions. Alternatively, one or more second concave portions 120 can be disposed in rows corresponding to the circuit patterns 130 in a one-to-one correspondence.

When the semiconductor chip 200 is mounted on the first concave portion 110 of the substrate 100, the semiconductor chip 200 is attached to the substrate 100 by the adhesive 140. The side surface of wiring layer 260 of the semiconductor chip 200 contacts and is electrically connected to the circuit patterns 130 of the substrate 100. Subsequently, an adhesive layer 270 is formed using an electroplating method on the side surface of seed layer 250 formed in the via-holes 217 and exposed as illustrated in FIG. 1. The adhesive layer 270 strengthens the adhesive force between the wiring layer 260 of the semiconductor chip 200 and the circuit patterns 130 of the substrate 100. Likewise, since the wiring layer 260 of the semiconductor chip 200 directly contacts the circuit patterns 130 of the substrate 100, a wire bonding process for connecting them can be omitted.

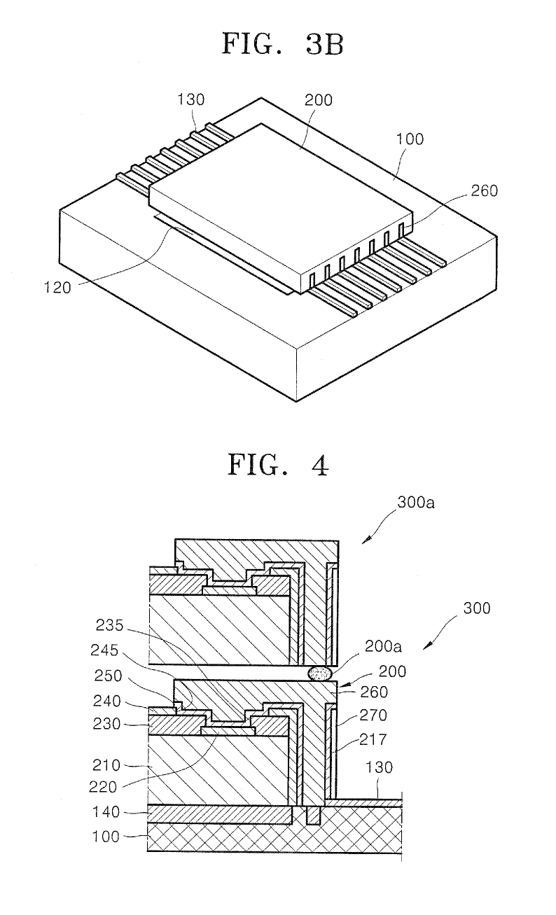

FIG. 4 is a cross-sectional view of a semiconductor package 300a according to another embodiment of the present invention. Referring to FIG. 4, the semiconductor package 300a includes two stacked semiconductor chips 200 and the structure of each semiconductor chip 200 is the same as explained with regard to FIG. 1. The upper and lower semiconductor chips 200 are stacked and electrically connected to each other through a solder ball 200a. Alternatively, the upper and lower semiconductor chips 200 can be electrically connected by a direct contact between the wiring layers 260 of the upper and lower semiconductor chips 200 without the solder ball 200a. Also, the upper and lower semiconductor chips 200 may be electrically connected by an external connection terminal, for example, a solder bump or an anisotropic conductive film.

According to the above embodiments of the present invention, a wiring bonding process can be omitted by forming a concave portion in a printed circuit board to prevent an adhesive from overflowing and directly contacting an exposed side surface of wiring layer of a semiconductor chip to circuit patterns of the printed circuit board. Thus, a packaging process can be simplified and the manufacturing costs as well as processing time can be reduced. Further, the adhesive force between circuit patterns of the printed circuit board and the wiring layers can be strengthened by electroplating on the exposed side surface of the wiring layer.

According to an aspect of the present invention, there is provided a semiconductor package in which a semiconductor chip is electrically connected to a substrate. The semiconductor package comprises a substrate and a semiconductor chip. The substrate comprises a first concave portion formed on the upper surface thereof and a plurality of circuit patterns disposed adjacent to the first concave portion. The semiconductor chip is mounted on the substrate so as to substantially correspond to the first concave portion. The semiconductor chip comprises: a wafer; pads disposed on the wafer; and wiring layers disposed on the upper surface and one side surface of the wafer, in which first portions of the wiring layers disposed on the upper surface of the wafer are connected to the pads and second portions of the wiring layers disposed on the side surface of the wafer contact the circuit patterns.

The semiconductor chip is attached to the substrate by an adhesive in the first concave portion. The semiconductor chip can be multi-stacked, and the wiring layers of the stacked semiconductor chips can be electrically connected to each other through solder balls, or the wirings layers can be directly electrically connected to each other.

The substrate further comprises a second concave portion formed at least between the first concave portion and the circuit patterns. The second portions of the wiring layers are disposed to correspond to the second concave portion and electrically contact the circuit patterns. The second concave portions are formed on the upper surface of the substrate so as to substantially surround the first concave portion.

A plurality of the second concave portions are disposed at least between the first concave portion and the circuit patterns so as to correspond to the circuit patterns in a one-to-one correspondence.

The semiconductor chip further comprises: a first insulation layer disposed on the upper surface of the wafer and comprising first openings to expose portions of the pads; and a second insulation layer disposed in the upper surface of the first insulation layer and on the one side surface of the wafer, the second insulation layer comprising: second openings exposing the portions of the pads; and via-holes formed on one side of the wafer, wherein the second portions of the wiring layers are disposed in the via-holes.

The semiconductor chip further comprises a seed layer disposed on the upper surface of the second insulation layer, on the pad, and in the via-hole, the seed layer connecting the pad with the wiring layer and the wiring layer with the circuit pattern.

The semiconductor chip further comprises an adhesive layer for enhancing the adhesive force between the second portion of the wiring layer and the circuit pattern.

According to another aspect of the present invention, there is provided a method of manufacturing a semiconductor package. Firstly, a wafer comprising a plurality of semiconductor chip areas defined by scribe areas comprising a scribe line is provided. At least one semiconductor chip comprising: a plurality of pads respectively disposed on an upper surface of the semiconductor chip areas of the wafer; and a plurality of wiring layers disposed on the upper surface of the wafer in the semiconductor chip areas and on one side surface of the wafer in the scribe areas and respectively connected to the pads is manufactured. A substrate comprising a first concave portion on an upper surface thereof and a plurality of circuit patterns disposed on the upper surface of the substrate adjacent to the first concave portion is arranged. The at least one semiconductor chip is mounted on the substrate so as to correspond to the first concave portion, so that each of the wiring layers of the semiconductor chip contacts the circuit pattern.

An adhesive layer for enhancing the adhesive force between the wiring layer and the circuit pattern is further formed after mounting the semiconductor chip on the substrate. The adhesive layer is formed of a metal layer using an electroplating method.

To manufacture the at least one semiconductor chip, the plurality of pads are formed in the semiconductor chip areas of the wafer and a concave portion is formed by etching the wafer of the scribe area to a predetermined thickness. An insulation layer is formed on the concave portion of the scribe area, the pads of the semiconductor chip area and the wafer. Openings exposing portions of the pads are formed and via-holes are formed on both sides of the scribe line in the scribe area by etching the insulation layer. Wiring layers contacting the pads of the semiconductor chip area are formed on the upper surface of the wafer so that the wiring layers are disposed in the via-holes. A rear surface of the wafer is lapped. An adhesive tape is attached on the rear surface of the lapped wafer. The insulation layer and a portion of the adhesive tape are cut along the scribe line. The adhesive tape and a portion of the insulation layer in the scribe area are removed.

The adhesive tape and the portion of the insulation layer are removed by irradiating ultraviolet rays on the adhesive tape. A protection layer defining openings exposing portions of the pads is formed prior to the forming of the insulation layer.

To form the wiring layer, a seed layer is formed on the upper surface of the wafer. Photoresist patterns are formed on second portions of the seed layer to expose first portions of the seed layer corresponding to the via-holes, pads, and a portion between the via-holes and the pads in each of the semiconductor chip areas. The wiring layers are formed on the exposed first portions of the seed layer so that the wiring layers are partially disposed in the via-holes and contact the pads. The second portions of the seed layer are exposed by removing the photoresist patterns. The insulation layer is exposed by removing the exposed second portions of the seed layer. The wiring layer is formed using a plating method.

The lapping of the rear surface of the wafer is performed until the wiring layer buried in the via-holes is exposed.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a substrate comprising a first concave portion disposed on an upper surface thereof and a plurality of circuit patterns disposed adjacent to the first concave portion; and
at least one semiconductor chip mounted on the substrate, the semiconductor chip substantially corresponding to the first concave portion and comprising:
a wafer;
pads disposed on the wafer; and
wiring layers disposed on an upper surface and one side surface of the wafer, wherein first portions of the wiring layers disposed on the upper surface of the wafer are connected to the pads and second portions of the wiring layers disposed on the side surface of the wafer contact the circuit patterns.

2. The semiconductor package of claim 1, wherein the semiconductor chip is attached to the substrate by an adhesive in the first concave portion.

3. The semiconductor package of claim 1, wherein the substrate further comprises a second concave portion disposed between the first concave portion and the circuit patterns, and wherein the second portions of the wiring layers are disposed so as to correspond to the second concave portion.

4. The semiconductor package of claim 3, wherein one or more second concave portions are disposed on the upper surface of the substrate so as to substantially surround the first concave portion.

5. The semiconductor package of claim 3, wherein a plurality of the second concave portions are disposed between the first concave portion and the circuit patterns so as to correspond to the circuit patterns in a one-to-one correspondence.

6. The semiconductor package of claim 1, wherein the semiconductor chip further comprises:
a first insulation layer disposed on the upper surface of the wafer and defining first openings to expose portions of the pads; and
a second insulation layer disposed on the upper surface of the first insulation layer and on the one side surface of the wafer, wherein the second insulation layer comprises:
second openings exposing the portions of the pads; and
via-holes disposed on one side of the wafer,
wherein the second portions of the wiring layers are disposed in the via-holes.

7. The semiconductor package of claim 6, wherein the first insulation layer comprises a protection layer and the second insulation layer comprises an interlayer insulating layer.

8. The semiconductor package of claim 6, wherein the semiconductor chip further comprises a seed layer disposed on an upper surface of the second insulation layer, on the pad, and in the via-hole, and wherein the seed layer connects the pad with the wiring layer and the wiring layer with the circuit pattern.

9. The semiconductor package of claim 1, wherein the semiconductor chip further comprises an adhesive layer to enhance adhesion between the second portion of the wiring layer and the circuit pattern.

10. The semiconductor package of claim 1, wherein two or more semiconductor chips are stacked and the wiring layers of upper and lower semiconductor chips are electrically connected directly or through an external connection terminal.
